(19) United States
(12) Patent Application Publication
(10) Pub. No.: US 2025/0052802 A1
(43) Pub. Date: Feb. 13, 2025

(54) SUPPLY CIRCUIT HAVING A COMPUTER DEVICE FOR DIAGNOSING A CONNECTING CIRCUIT, IN PARTICULAR FOR POWER ELECTRONICS IN A VEHICLE, AND METHOD FOR OPERATING A SUPPLY CIRCUIT HAVING A COMPUTER DEVICE FOR DIAGNOSING A CONNECTING CIRCUIT

(71) Applicant: Robert Bosch GmbH, Stuttgart (DE)

(72) Inventor: Axel Haas, Oberstenfeld (DE)

(21) Appl. No.: 18/719,629

(22) PCT Filed: Oct. 24, 2022
(86) PCT No.: PCT/EP2022/079569

§ 371 Date: Jun. 13, 2024

(30) Foreign Application Priority Data
Dec. 16, 2021 (DE) 10 2021 214 483.7

(51) Int. Cl. G01R 31/00; H02J 1/08

(52) U.S. Cl. CPC G01R 31/006; H02J 1/082; H02J 2310/46

(57) ABSTRACT

A supply circuit (100) having a computer device (110) for diagnosing a connecting circuit (120), in particular for power electronics in a vehicle, wherein the supply circuit (100) comprises a first and a second supply source (102, 104) for supplying a first and a second consumer (202, 204). The supply circuit (100) comprises a computer device (110). The computer device (110) is configured to determine an applied second supply voltage (UA2) on the second consumer (204) and to diagnose the correct operation of the connecting circuit (120) on the basis of the determined applied second supply voltage (UA2).

### BACKGROUND

The invention relates to a supply circuit having a computer device for diagnosing a connecting circuit and a method for operating a supply circuit using a computer device for diagnosing a connecting circuit. The invention also relates to a drive train having a supply circuit, a vehicle having a drive train, as well as computer program and a computer-readable medium.

A large number of control units are installed in vehicles to control a wide variety of functions to, e.g., control a drive motor, brakes, steering or comfort functions such as air conditioning and seat adjustment. These control units are connected to the vehicle's electrical system to supply electrical energy. This electrical system usually has a voltage of 12 volts. However, the control units control different circuits or consumers that have additional operating voltages, e.g. 5 volts for a computing unit, 15 volts for controlling switching elements, 20 volts for hydraulic components. For this reason, there are supply circuits within the control units that convert the voltage from the vehicle electrical system into the desired operating voltage or supply voltage. For safety-relevant functions or consumers, these supply circuits are designed redundantly, i.e. comprising multiple supply sources. A consumer can therefore be supplied in parallel from two supply sources. A reliable power supply is thus guaranteed. Furthermore, if a single fault occurs, then it is possible to continue operating the consumer safely using the redundant supply source and to bring the consumer or a system surrounding the consumer, preferably consisting of multiple control devices, into a safe state. The fault can then be rectified. This ensures a safe, reliable power supply for the next operation. It is known to design such redundant supply circuits using two supply sources. A supply source often comprises at least two switched-mode power supplies to provide at least two operating voltages or supply voltages. Multiple circuits or consumers at different operating voltages are thus supplied. For redundant operation of the supply sources, supply voltages of the same size are connected in parallel. A fault, e.g. a short circuit of a supply voltage to another potential or earth, would result in a high current. This high current flow leads to the breakdown of all the supply voltages provided by the supply sources. There is therefore a need for solutions that can detect such a fault and, in such a case, enable the continued safe operation of at least one of the supply sources. In addition, the operational readiness of such a solution must be guaranteed at all times. It must therefore be possible to monitor a corresponding solution and diagnose its functionality.

### SUMMARY

A supply circuit having a computer device for diagnosing a connecting circuit is provided, in particular for power electronics in a vehicle. The supply circuit comprises at least one first and one second supply source for supplying at least one first and at least one second consumer. The first supply source is configured to provide a first supply voltage for the first consumer after the first supply source is switched on and to provide a third supply voltage for the connecting circuit, whereby the third supply voltage can also be provided to the second consumer by means of the connecting circuit. The second supply source is configured to provide a second supply voltage for the second consumer after the second supply source is switched on. The connecting circuit is configured to electrically connect the third supply voltage to the second consumer by closing a switching element and to disconnect the third supply voltage from the second consumer by opening the switching element. The supply circuit comprises a computer device. The computer device is configured to determine an applied second supply voltage on the second consumer and to diagnose the correct operation of the connecting circuit based on the second supply voltage determined.

The power electronics in a vehicle is preferably a voltage converter. A voltage converter is preferably in an inverter or a DC-DC converter. The inverter is preferably used to convert the DC voltage of a battery into a multi-phase voltage to supply an electrical machine, which is preferably configured to drive the vehicle. A DC/DC converter is preferably used to convert the high voltage of a vehicle's battery into the operating voltage of the vehicle's electrical system or vice versa. A DC/DC converter in a vehicle charger is preferably used to adapt the charging voltage to the battery voltage of the battery to be charged.

Preferably, the computer device of the supply circuit is a control device, a microcontroller, or a regulator, which is configured to receive data, signals, or information from at least one consumer and preferably to transmit them to at least one of the consumers. Preferably, the computer device is configured to switch on a first or second supply source. Preferably, switching on a supply source involves connecting the supply source on the input side to a supply network, preferably a supply network of an electrical system or an on-board network of a vehicle. Preferably, a supply source comprises at least one switching power supply or a DC/DC converter that converts an input voltage into an output voltage and provides it as a supply voltage at output terminals. Preferably, a supply source comprises a first and a second switched-mode power supply unit or a first and a second DC/DC converter for providing a first and a second supply voltage. Preferably, the output terminals of a switched-mode power supply or a DC/DC converter are galvanically connected to the input terminals of a consumer via connecting cables. Preferably, providing a supply voltage for a consumer means that after the supply source is switched on, the supply voltage is provided to the consumer via the connecting cables and is therefore present at the input terminals of the consumer. Preferably, the third supply voltage can also be provided to the second consumer by means of the connecting circuit, in that a switching element in the connecting circuit is closed and the third supply voltage is provided to the second consumer by the connecting circuit via connection lines between the connecting circuit and the second consumer. Preferably, the connection lines between the connecting circuit and the second consumer and the connection lines between the second supply source and the second consumer are connected together, preferably in parallel. Preferably, this enables the second consumer to be supplied by both the first and the second supply source. Preferably, the third supply voltage is connected to the second consumer by closing a switching element by electrically connecting the connection lines between the first supply source of the third supply voltage and the connecting circuit to the connection lines between the connecting circuit and the second consumer. Preferably, the third supply voltage is disconnected from the second consumer by opening the switching element by electrically disconnecting the connection lines between the first supply source of the third supply voltage and the connecting circuit from the connection lines between the connecting circuit and the second consumer. Preferably, disconnection is performed when there is a short circuit in the second supply voltage, preferably to earth or another potential. Preferably, the computer device determines an applied second supply voltage at the second consumer by receiving data, information, or signals relating to the applied second supply voltages from the second consumer. Preferably, the second consumer comprises a voltage measuring device for detecting the applied second supply voltage. Preferably, the second consumer transmits the determined second supply voltage applied as data, information, or as a signal to the computer unit. Preferably, the computer device does not interpret a second supply voltage applied to the second consumer if the computer device does not receive any data or information from the second consumer. Alternatively, the computer device comprises a voltage measuring device to determine the second supply voltage applied to the second consumer. Preferably, the computer device diagnoses the correct operation of the connecting circuit on the basis of the determined applied second supply voltage by forming and evaluating a difference between a determined applied second supply voltage at a first point in time and a determined applied second supply voltage at a second point in time, or by comparing points in time at which a determined applied second supply voltage has a first voltage value and at which a determined applied second supply voltage has a second voltage value, or by evaluating a combination of the information. Preferably, the computer device diagnoses a defect in the connecting circuit if the difference falls below a specifiable difference threshold value, or if the determined applied second supply voltage does not change over a time period that exceeds a specifiable time period value. Operation of the first supply source or the supply circuit is preferably stopped if a defect is diagnosed. Advantageously, a supply circuit is provided that enables a connecting circuit to be diagnosed. Preferably, no direct or physical connection between the computer unit and the connecting circuit is required. This enables a particularly simple implementation of a supply circuit with a computer device for diagnosing a connecting circuit in a control unit.

In another embodiment of the invention, the switching element of the connecting circuit is open as long as the third supply voltage is not applied to the connecting circuit.

The switching element of the connecting circuit is preferably an electronically controlled switch that opens automatically as long as the third supply voltage is not applied to the connecting circuit. Therefore, connecting circuit preferably disconnects the first supply source from the second consumer as long as no third supply voltage is provided by the connecting circuit. Advantageously, a supply circuit is provided in which the second consumer is electrically isolated from the supply circuit when switched off.

In another embodiment of the invention, the connecting circuit comprises a switching delay device and is configured to close the switching element after a specifiable first period of time after the third supply voltage is applied to the connecting circuit.

Preferably, the switching delay device is configured by means of software or hardware to close the switching element after a specifiable first period of time after the third supply voltage is applied to the connecting circuit. Preferably, the specifiable first time period is approximately 0.1 to 1 second. Advantageously, a behavior of the connecting circuit is provided, which advantageously enables an improved diagnosis of the connecting circuit by the computer unit.

In another embodiment of the invention, the computer device is set up to switch on the first supply source and to diagnose the correct operation of the connecting circuit if, upon expiry of a specifiable switch-on duration after the first supply source has been switched on, the second supply voltage present corresponds to a second specifiable voltage value and, after subsequent expiry of the first duration, the second supply voltage present corresponds to a third specifiable voltage value.

Preferably, the first supply source provides a third supply voltage for the connecting circuit after a specifiable switch-on time has elapsed after the first supply source has been switched on. Preferably, the specifiable duty cycle is approximately 0.1 to 1 second. Preferably, the provision of the third supply voltage for the connecting circuit lasts as long as the specified duty cycle. Preferably, the second voltage value corresponds to zero volts. Due to the switching delay immediately after the third supply voltage for the connecting circuit is provided, the third supply voltage is not initially applied to the second consumer because the switch is open. The second supply voltage applied to the second consumer is therefore preferably zero volts when the switch is open when used as intended. Due to the switching delay, the second applied supply voltage is preferably then a third voltage value after the first time period has elapsed, whereby this preferably corresponds to the third supply voltage, which is now provided to the second consumer by means of the closed switch of the connecting circuit. A fault is preferably diagnosed if the applied second supply voltage deviates from the specified voltage values. Preferably, a fault is diagnosed if the second applied supply voltage corresponds to the third voltage value after the specifiable switch-on time has elapsed after the first supply source is switched on or if the applied second supply voltage corresponds to the second voltage value after the first time has elapsed. Operation of the first supply source or the supply circuit is preferably stopped if a defect is diagnosed. Advantageously, a supply circuit is provided that enables improved diagnosis of the connecting circuit. Preferably, a diagnosis is provided that ensures the correct operation of the switching element. Preferably, the correct operation of the switching element is that it opens if the third supply voltage is not provided for the connecting circuit or as long as the first time period of the switching delay device has not yet elapsed.

In another embodiment of the invention, the computer device is configured to determine an applied first supply voltage on the first consumer and to diagnose the correct operation of the connecting circuit on the basis of the determined applied first and second supply voltages.

Preferably, the computer device determines an applied first supply voltage on the first consumer and an applied second supply voltage at the second consumer by receiving data, information, or signals relating to the applied supply voltages from the consumers. Preferably, the computer device determines an applied first supply voltage on the first consumer or an applied second supply voltage at the second consumer by evaluating the receipt of data, information, or signals from the respective consumer as the presence of the respective applied supply voltage. Preferably, the consumers comprise voltage measuring devices for detecting the applied supply voltages and transmit these as data, information, or signals to the computer device. Preferably, the consumers transmit the determined applied supply voltages to the computer unit as data, information, or as a signal. Preferably, the computer device does not interpret any supply voltage applied to the consumer if the computer device does not receive any data or information from the consumer. Alternatively, the computer device comprises voltage measuring devices in order to determine the supply voltages applied to the consumers. Preferably, the computer device diagnoses the correct operation of the connecting circuit on the basis of the determined applied first and second supply voltage by forming and evaluating a difference between the determined applied first and second supply voltages or by comparing the times at which the first and second supply voltages are applied or by evaluating a combination of the information. Preferably, the computer device diagnoses a defect in the connecting circuit if the difference exceeds a specifiable difference threshold value, or if only one of the applied supply voltages is present for a period of time that exceeds a specifiable time duration value. Operation of the first supply source or the supply circuit is preferably stopped if a defect is diagnosed. Advantageously, a supply circuit is provided that enables a connecting circuit to be diagnosed. Preferably, no direct or physical connection between the computer unit and the connecting circuit is required for this purpose. This enables particularly simple implementation in a control unit.

In another embodiment of the invention, the computer device is configured to diagnose the correct operation of the connecting circuit if initially the first applied supply voltage corresponds to a first specifiable voltage value and the second applied supply voltage corresponds to a second specifiable voltage value and after subsequent expiry of the first time period the second applied supply voltage corresponds to a third specifiable voltage value and in particular the first applied supply voltage corresponds to the first specifiable voltage value.

Preferably, the second voltage value corresponds to zero volts, as the first supply voltage is only applied to the first consumer immediately after the third supply voltage is provided for the connecting circuit due to the switching delay and the third supply voltage is not applied to the second consumer due to the open switch. The applied second supply voltage on the second consumer is therefore preferably zero volts when the switch is open as intended. Due to the switching delay, the second applied supply voltage is preferably a third voltage value after the first time period has elapsed, whereby this preferably corresponds to the third supply voltage, which is now provided to the second consumer by means of the closed switch of the connecting circuit. Preferably, the first applied supply voltage still corresponds to the first specifiable voltage value. A fault is preferably diagnosed if the applied supply voltages deviate from the specified voltage values. Preferably, a fault is diagnosed if the first applied supply voltage corresponds to a first specifiable voltage value at the start of the diagnosis and the second applied supply voltage corresponds to the third voltage value or the second applied supply voltage corresponds to the second voltage value after the first time period has elapsed. Operation of the first supply source or the supply circuit is preferably stopped if a defect is diagnosed. Advantageously, a supply circuit is provided that enables improved diagnosis of the connecting circuit. Preferably, a diagnosis is provided that ensures the correct operation of the switching element. Preferably, the correct operation of the switching element is that it opens if the third supply voltage is not provided for the connecting circuit or as long as the first time period of the switching delay device has not yet elapsed.

In another embodiment of the invention, the first supply source is switched on first and the second supply source is only switched on after the first time period and a second specifiable time period have elapsed.

After switching on, the second supply source provides a second supply voltage for the second consumer. So that the resulting voltage applied to the second consumer cannot be incorrectly determined as the second applied supply voltage during the diagnosis, the second supply source is only switched on after the first time period has elapsed after the first supply source has been switched on and a second specifiable time period has elapsed. Preferably, the second specifiable time period is approximately one to four seconds. Advantageously, a supply circuit is provided that enables improved diagnosis of the connecting circuit.

In another embodiment of the invention, the connecting circuit comprises a current measuring device for determining a load current through the closed switching element. The connecting circuit is also configured to open the switching element if the load current determined exceeds a first specifiable current value.

If the second supply voltage is short-circuited to earth or another potential, there is a risk that a very large load current will develop, which will also flow through the connecting circuit. This leads to a breakdown of the first and third supply voltage provided by the first supply source. To ensure a further reliable supply to at least the first consumer, the connection lines between the first supply source and the second consumer are disconnected by opening the switching element of the connecting circuit. For this purpose, the connecting circuit opens the switching element when a determined load current exceeds a first predefinable current value. Safe operation of a supply circuit with a computer device for diagnosing a connecting circuit is advantageously ensured, whereby an intrinsically safe connecting circuit is provided.

The invention also relates to a drive train having a supply circuit. In addition to the supply circuit, a drive train preferably comprises a battery for supplying the drive train, an inverter for converting the DC voltage of the battery into an AC voltage for supplying an electric machine and/or the electric machine. Advantageously, a drive train is provided that enables a connecting circuit to be diagnosed.

The invention also relates to a vehicle comprising a drive train. A vehicle can be a vehicle on land, in the water, or in the air, preferably a motor vehicle. Advantageously, a vehicle is provided that enables a connecting circuit to be diagnosed.

Furthermore, the invention relates to a method for operating a supply circuit, comprising the following steps: determining a second supply voltage applied to the second consumer; diagnosing the correct operation of the connecting circuit on the basis of the determined applied second supply voltage. Advantageously, a method for operating a supply circuit is provided, which enables diagnosis of a connecting circuit.

Furthermore, the invention relates to a computer program comprising instructions which cause the computer device of the supply circuit to perform the steps of the method.

The invention further relates to computer-readable media comprising instructions which, when executed by the computer device of the supply circuit, prompt the latter to perform the steps of the method.

It is understood that the features, properties, and advantages of the supply circuit apply or can be applied accordingly to the method or the drive train and the vehicle and vice versa.

### BRIEF DESCRIPTION OF THE DRAWINGS

Further features and advantages of embodiments of the invention are apparent from the following description with reference to the accompanying drawings.

The invention will be explained in further detail hereinafter with reference to the drawings:

FIG. 1 a schematic representation of a supply circuit having a computer device for diagnosing a connecting circuit.

FIG. 2 a schematic representation of a vehicle having a drive train with a supply circuit,

FIG. 3 a schematically illustrated method for operating a supply circuit.

### DETAILED DESCRIPTION

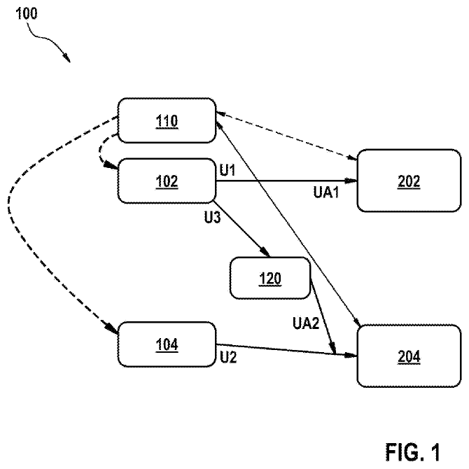

FIG. 1 shows a supply circuit 100 having a computer device 110 for diagnosing a connecting circuit 120. The supply circuit 100 comprises a first and a second supply source 102, 104 for supplying a first and a second consumer 202, 204. The first supply source 102 is configured to provide a first supply voltage Ul for the first consumer 202 and a third supply voltage U3 for the connecting circuit 120 after the first supply source is switched on. The third supply voltage U3 can also be provided to the second consumer 204 by means of the connecting circuit 120. The second supply source 104 is configured to provide a second supply voltage U2 for the second consumer 204 after the second supply source is switched on. The connecting circuit 120 is configured to electrically connect the third supply voltage U3 to the second consumer 204 by closing a switching element and to disconnect the third supply voltage U3 from the second consumer 204 by opening the switching element. The supply circuit 100 comprises a computer device 110. Preferably, the computer device 110 is configured to switch on the first and or second supply source 102, 104. The computer device 110 is configured to determine an applied second supply voltage UA2 at the second consumer 204. Preferably, the computer device 110 is configured to determine an applied first supply voltage UA1 on the first consumer 202. Furthermore, the computer device 110 is configured to diagnose the correct operation of the connecting circuit 120 on the basis of the determined applied second and or first supply voltage UA1, UA2.

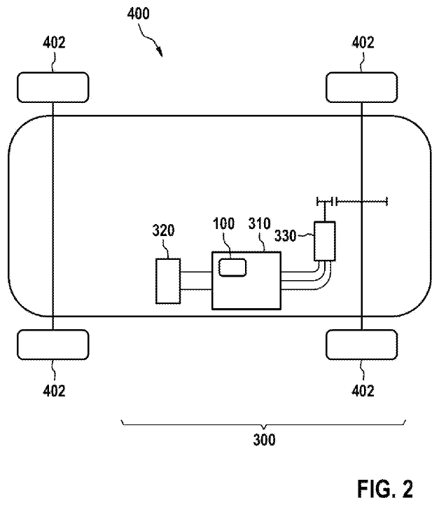

FIG. 2 shows a schematic representation of a vehicle 400 comprising four wheels 402 and a drive train 300. The vehicle 400 is in this case shown (only by way of example) as comprising four wheels 402, whereby the invention can be used equally in any vehicle with any desired number of wheels on land, on water, and in the air. The exemplary drive train 300 comprises a supply circuit 100, which is preferably integrated into an inverter 310. The drive train 300 preferably comprises a battery 320, an inverter 310 and or an electric machine 330.

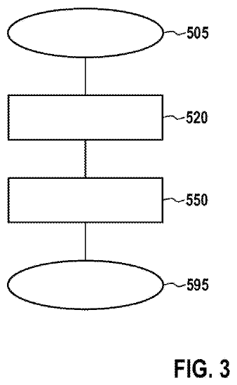

FIG. 3 shows a schematic flow chart for a method 500 for operating a supply circuit 100. The method begins with step 505. In step 520, an applied second supply voltage UA2 is determined at the second consumer 204. In step 550, the correct operation of the connecting circuit 120 is diagnosed on the basis of the determined applied second supply voltage UA2. The method ends with step 595.

1. A supply circuit (100) having a computer device (110) for diagnosing a connecting circuit (120) for power electronics in a vehicle,
wherein the supply circuit (100) comprises a first and a second supply source (102, 104) for supplying a first and a second consumer (202, 204),
wherein the first supply source (102) is configured to provide a first supply voltage (Ul) for the first consumer (202) after the first supply source (102) is switched on and to provide a third supply voltage (U3) for the connecting circuit (120), wherein the third supply voltage can also be provided to the second consumer (204) by means of the connecting circuit (120),
wherein the second supply source (104) is configured to provide a second supply voltage (U2) for the second consumer (204) after the second supply source (104) is switched on,
wherein the connecting circuit (120) comprises a switching element and is configured to electrically connect the third supply voltage (U3) to the second consumer (204) by closing the switching element and to disconnect the third supply voltage (U3) from the second consumer (204) by opening the switching element,
wherein the supply circuit (100) comprises a computer device (110), and
wherein the computer device (110) is configured to determine an applied second supply voltage (UA2) on the second consumer (204),
and to diagnose the correct operation of the connecting circuit (120)
based on the determined applied second supply voltage (UA2).

2. The supply circuit according to claim 1, wherein the switching element of the connecting circuit (120) is open as long as the third supply voltage (U3) is not applied to the connecting circuit (120).

3. The supply circuit according to claim 1, wherein the connecting circuit (120) comprises a switching delay device and is configured to close the switching element after a specifiable first time period after the third supply voltage (U3) is applied to the connecting circuit (120).

4. The supply circuit according to claim 3, wherein the computer device (110) is configured to switch on the first supply source (102) and to diagnose the correct operation of the connecting circuit (120) if, on expiry of a specifiable switch-on duration after switching on the first supply source, the second applied supply voltage (UA2) corresponds to a second specifiable voltage value (US2) and, after subsequent expiry of the first duration, the second applied supply voltage (UA2) corresponds to a third specifiable voltage value (US3).

5. The supply circuit according to claim 1, wherein the computer device is configured to determine an applied first supply voltage (UA1) on the first consumer (202), and to diagnose the correct operation of the connecting circuit (120) on the basis of the determined applied first and second supply voltage (UA1, UA2).

6. The supply circuit according to claim 5, wherein the computer device (110) is configured to diagnose the correct operation of the connecting circuit (120) when the first applied supply voltage (UA1) initially corresponds to a first specifiable voltage value (US1) and the second applied supply voltage (UA2) corresponds to a second specifiable voltage value (US2) and, after subsequent expiry of the first time period, the second applied supply voltage (UA2) corresponds to a third specifiable voltage value (US3) and the first applied supply voltage (UA1) corresponds to the first specifiable voltage value (US1).

7. The supply circuit according to claim 1, wherein the first supply source (102) is switched on first, and the second supply source (104) is switched on only after the first time period and a second specifiable time period have elapsed.

8. The supply circuit according to claim 1, wherein the connecting circuit (120) comprises a current measuring device for determining a load current through the closed switching element and is configured to open the switching element when the determined load current exceeds a first specifiable current value.

9. A drive train (300) of a vehicle having a supply circuit (100) according to claim 1.

10. A vehicle (400) having a drive train (300) according to claim 9.

11. A method (500) for operating a supply circuit (100) for power electronics in a vehicle, according to claim 1, said method comprising the following steps:
determining (520) an applied second supply voltage (UA2) on the second consumer (204);
diagnosing (550) the correct operation of the connecting circuit (120) on the basis of the determined applied second supply voltage (UA1, UA2).

12. (canceled)

13. A non-transitory, computer-readable medium comprising instructions which, when executed by a computer (110) of a supply circuit (100) cause the computer to determine (520) an applied second supply voltage (UA2) on a second consumer (204);
diagnose (550) the correct operation of a connecting circuit (120) based on the determined applied second supply voltage (UA1, UA2),
wherein the supply circuit 100 comprises a first and a second supply source (102, 104) for supplying a first and the second consumer (202, 204),
wherein the first supply source (102) is configured to provide a first supply voltage (Ul) for the first consumer (202) after the first supply source (102) is switched on and to provide a third supply voltage (U3) for the connecting circuit (120), wherein the third supply voltage is also provided to the second consumer (204) via the connecting circuit (120),
wherein the second supply source (104) is configured to provide a second supply voltage (U2) for the second consumer (204) after the second supply source (104) is switched on, wherein the connecting circuit (120) comprises a switching element and is configured to electrically connect the third supply voltage (U3) to the second consumer (204) by closing the switching element and to disconnect the third supply voltage (U3) from the second consumer (204) by opening the switching element.
